(19) United States
(12) Patent Application Publication
(10) Pub. No.: US 2025/0285973 A1
(43) Pub. Date: Sep. 11, 2025

(54) SOURCE/DRAIN CONTACT CUT AND POWER RAIL NOTCH

(71) Applicant: International Business Machines Corporation, Armonk, NY (US)

(72) Inventors: Brent A. Anderson, Jericho, VT (US); Nicholas Anthony Lanzillo, Wynantskill, NY (US); Albert M. Chu, Nashua, NH (US); Ruilong Xie, Niskayuna, NY (US); Lawrence A. Clevenger, Saratoga Springs, NY (US); Reinaldo Vega, Mahopac, NY (US)

(21) Appl. No.: 18/596,892

(22) Filed: Mar. 6, 2024

(51) Int. Cl. H01L 23/528; H01L 21/3213; H01L 29/417

(52) U.S. Cl. CPC H01L 23/5286; H01L 21/32139; H10D 64/251

(57) ABSTRACT

Embodiments of the invention include a method for fabricating a device and the resulting structure. A transistor source/drain contact is formed in a first orientation. A power rail is formed on the transistor source/drain contact in a second orientation, where the second orientation is perpendicular to the first orientation. A hardmask is formed. The hardmask is patterned to expose a location of an intersection of the power rail and the transistor source/drain contact. The location unprotected by the hardmask is etched to create a cut passing through the power rail and the transistor source/drain contact.

### BACKGROUND

The present invention relates generally to the field of semiconductor devices and fabrication, and more particularly to the formation and resulting structure of a source/drain contact and power rail.

A power delivery network is designed to provide power supply and reference voltage to active devices. Traditionally, this is realized as a network of low-resistive metal wires fabricated through back end of line (BEOL) processing on the frontside of a wafer.

A power rail is a metal line construct that acts as a voltage source within a device from which power can be drawn.

BEOL is the portion of integrated circuit fabrication where individual devices (e.g., transistors, capacitors, resistors) get interconnected with wiring. BEOL generally begins with the first layer of metal deposited on the structure. BEOL includes, for example, contacts, insulating layers, metal levels.

### SUMMARY

Embodiments of the invention include a structure that includes a transistor source/drain contact in a first orientation. The structure further includes a power rail on the transistor source/drain contact in a second orientation, where the second orientation is perpendicular to the first orientation. The structure further includes a cut passing through the power rail and the transistor source/drain contact at a location of intersection of the power rail and the transistor source/drain contact.

Embodiments of the invention also include a structure that includes a first source/drain contact with a length greater than a width, the length of the first source/drain contact in a first direction. The structure further includes a second source/drain contact with a length greater than a width, the length of the second source/drain contact in the first direction. The structure further includes a power rail with a length greater than a width, the length of the power rail in a second direction, where: the second direction is perpendicular to the first direction; the power rail contacts the first source/drain contact; and a notch is present within the power rail.

Embodiments of the invention include a method for fabricating a device. The method includes forming a transistor source/drain contact in a first orientation. The method can also include forming a power rail on the transistor source/drain contact in a second orientation, wherein the second orientation is perpendicular to the first orientation. The method can also include forming a hardmask. The method can also include patterning the hardmask to expose a location of an intersection of the power rail and the transistor source/drain contact. The method can also include etching the location unprotected by the hardmask to create a cut passing through the power rail and the transistor source/drain contact.

### BRIEF DESCRIPTION OF THE DRAWINGS

FIG. 1A depicts a top view of a process of forming a source/drain contact in a layer above front end of line (FEOL) device(s), in accordance with an embodiment of the invention.

FIG. 1B depicts a cross-sectional view, along section line A of FIG. 1A, in accordance with an embodiment of the invention.

FIG. 2A depicts a top view of a process of forming a power rail and interlayer dielectric, in accordance with an embodiment of the invention.

FIG. 2B depicts a cross-sectional view, along section line A of FIG. 2A, in accordance with an embodiment of the invention.

FIG. 3A depicts a top view of a process of forming and patterning a hardmask and forming a cut through the source/drain contact and power rail, in accordance with an embodiment of the invention.

FIG. 3B depicts a cross-sectional view, along section line A of FIG. 3A, in accordance with an embodiment of the invention.

FIG. 4A depicts a top view of a process of removing the hardmask, in accordance with an embodiment of the invention.

FIG. 4B depicts a cross-sectional view, along section line A of FIG. 4A, in accordance with an embodiment of the invention.

FIG. 5A depicts a top view of an example embodiment, in accordance with an embodiment of the invention.

FIG. 5B depicts a cross-sectional view, along section line A of FIG. 5A, in accordance with an embodiment of the invention.

FIG. 6A depicts a top view of an example embodiment, in accordance with an embodiment of the invention.

FIG. 6B depicts a cross-sectional view, along section line A of FIG. 6A, in accordance with an embodiment of the invention.

FIG. 7A depicts a top view of an example embodiment, in accordance with an embodiment of the invention.

FIG. 7B depicts a cross-sectional view, along section line A of FIG. 7A, in accordance with an embodiment of the invention.

FIG. 8A depicts a top view of an example embodiment, in accordance with an embodiment of the invention.

FIG. 8B depicts a cross-sectional view, along section line A of FIG. 8A, in accordance with an embodiment of the invention.

### DETAILED DESCRIPTION

Embodiments of the present invention recognize that critical circuit density can be significantly improved in structures with a connected power rail and contact with aligned ends when closer placement of a contact end to an adjacent power rail is allowed. Embodiments of the present invention utilize a source/drain contact cut and rail not to improve the density.

Embodiments of the present invention describe an approach for fabricating a semiconductor device, the approach including forming a front end of line transistor (FEOL). Embodiments of the present invention further describe forming a contact level, for example, a transistor source/drain contact. Embodiments of the present invention further describe forming a power rail level that is orthogonal to the contact level. Embodiments of the present invention further describe masking and etching the contact level and the power rail level to create a notch in the power rail and a cut in the length of the contact. Embodiments of the present invention further describe forming back end of line (BEOL) interconnect.

Embodiments of the present invention describe a resulting structure that includes at least a transistor source/drain contact in a first orientation. Embodiments of the present invention further describe a power rail in a perpendicular orientation to the transistor source/drain contact. Embodiments of the present invention further describe a notch in the power rail and that the source/drain contact is aligned (e.g., centered) with respect to the location of the notch. Embodiments of the present invention further describe that the distance from the inside of the notch edge of the power rail to the source/drain contact is less than the width of the power rail at areas of the power rail where the notch is not present. Embodiments of the present invention further describe the edge of the power rail notch being aligned with the end of the source/drain contact. Embodiments of the present invention further describe the power rail being directly connected to the underlying source/drain contact that is adjacent to the notch region. Embodiments of the present invention further describe that the width of the power rail notch may be wider than the width of the source/drain contact. Embodiments of the present invention further describe that the source/drain contact line end is aligned with the inside of the power rail notch. Embodiments of the present invention further describe that a distance from the end of the source/drain contact that is connected to the power rail to an adjacent contact is less than the width of the contact.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The present invention will now be described in detail with reference to the Figures.

It should be noted that embodiments of the present invention relate to contact and power rail levels of a semiconductor device. Accordingly, FEOL devices (e.g., transistors, capacitors, resistors) and further BEOL interconnect features of the semiconductor device are not depicted.

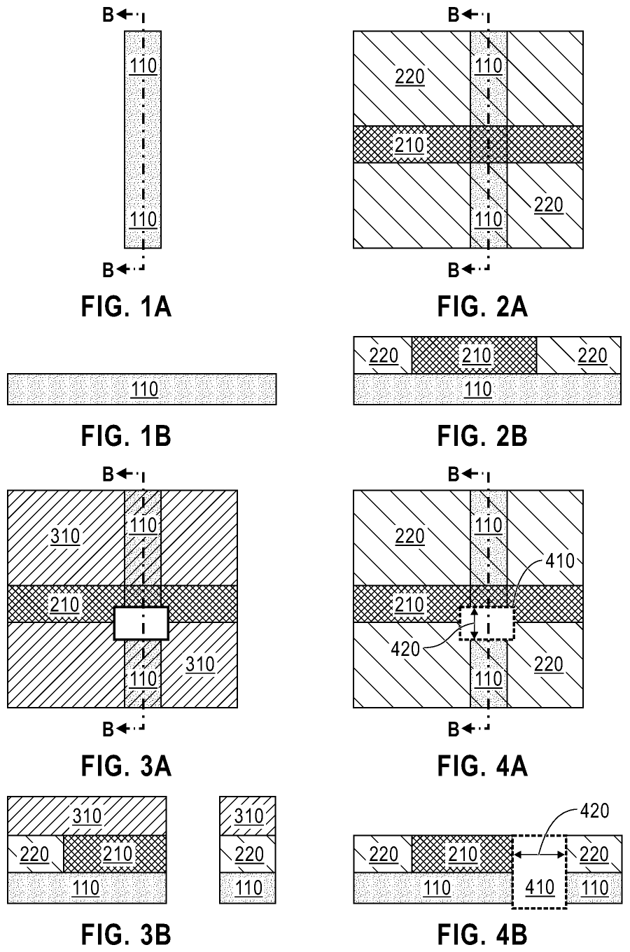

FIG. 1A depicts a top view of a device, at a stage subsequent to the formation of FEOL device(s), of fabrication steps in the method of forming the device. FIG. 1B depicts a cross-sectional view along section line A of FIG. 1A. FIGS. 1A-1B depict a process of forming source/drain contact 110 at a layer above present FEOL device(s) (not shown), in accordance with an embodiment of the present invention.

In general, source/drain contacts 110 are formed and make contact with a source/drain region of an FEOL device.

In some embodiments, an interlayer dielectric (ILD) material layer (not shown) may be formed over the FEOL device(s). ILD material may be composed of silicon dioxide, undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as the ILD material. The use of a self-planarizing dielectric material as the ILD material may avoid the need to perform a subsequent planarizing step.

In one embodiment, the ILD material can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as the ILD material, a planarization process or an etch back process follows the deposition of the dielectric material that provides the ILD material.

One or more trenches may be formed in the ILD material layer by lithography and an etching process, such as reactive-ion etching (RIE), laser ablation, or any etch process which can be used to selectively remove a portion of material such as the ILD material. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops at source/drain region(s) of the FEOL device(s). The trench or trenches correspond to the desired location of source/drain contact 110.

In some embodiments, subsequent to the formation of the trenches, the hardmask and ILD material is removed. In other embodiments, the hardmask is removed during a planarization step (e.g., chemical mechanical planarization (CMP)) after forming a damascene metal line. In such embodiments, the metal overfills the trench and is polished back to isolate the line segments. During the CMP process the top portion of the wafer is recessed, causing the hardmask to be removed. In other embodiments, the process of removing the hardmask and ILD material involves the use of an etching process such as RIE, laser ablation, or any etch process which can be used to selectively remove a portion of material, such as the hardmask and/or the ILD material. In some embodiments, prior to the removal of the hardmask, the photoresist (not shown) is removed. The process of removing the photoresist may be similar to that of the process of removing the hardmask.

Source/drain contact 110 may be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Source/drain contact 110 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

In other embodiments, rather than a damascene process for forming source/drain contact 110, a layer of material comprising source/drain contact 110 material may be deposited and, subsequently, an etching process (e.g., RIE, laser ablation), may be used to selectively remove portions of the source/drain contact 110 material to form source/drain contact 110. A patterned hardmask may be utilized to expose areas of the device where the source/drain contact 110 is not desired. The etching process only removes portions of the device not protected by the hardmask and stops the FEOL device(s).

Source/drain contact 110 may be formed such that source/drain contact 110 is a source/drain contact line in a first direction, wherein a length of the line is greater than a width.

FIG. 2A depicts a top view of fabrication steps and FIG. 2B depicts a cross-sectional view along section line A of FIG. 2A. FIGS. 2A-2B depict the formation of power rail 210 and ILD material 220, in accordance with an embodiment of the present invention.

A layer of ILD material 220 is formed above and around the source/drain contact 110. ILD material 220 may be composed of silicon dioxide, undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as ILD material 220. The use of a self-planarizing dielectric material as ILD material 220 may avoid the need to perform a subsequent planarizing step.

In one embodiment, ILD material 220 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 220, a planarization process or an etch back process follows the deposition of the dielectric material that provides ILD material 220.

One or more trenches may be formed in ILD material 220 by lithography and an etching process, such as reactive-ion etching (RIE), laser ablation, or any etch process which can be used to selectively remove a portion of material such as ILD material 220. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops at a top surface of source/drain contact 110. The trench or trenches correspond to the desired location of power rail 210.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

Power rail 210 may be formed by for example, depositing (e.g., by PVD), a metal layer (e.g., a thin adhesion TiN layer followed by bulk Cu, Co, or Ru fill) on exposed surfaces within the trench (e.g., source/drain contact 110). Any deposition process may be used for the formation of the metal layer including, for example, chemical vapor deposition (CVD), plasma enhanced chemical vapor deposition (PECVD), physical vapor deposition (PVD), plating, sputtering, or atomic layer deposition. In other embodiments, co-evaporation techniques may be utilized to form power rail 210. In yet other embodiments, known sputter deposition or chemical vapor deposition techniques may be utilized to form the silicide layer.

In some embodiments, power rail 210 is deposited such that power rail 210 surrounds the silicide layer and fills the remaining area of the trench. Power rail 210 may be in direct contact with the silicide layer and/or source/drain contact 110.

Power rail 210 can include a conductive material including, for example, Cu, Co, Ru, W with a thin adhesion liner such as, for example, TiN.

Power rail 210 can be formed utilizing a deposition process including, for example, plating, chemical vapor deposition (CVD), plasma enhanced chemical vapor deposition (PECVD), physical vapor deposition (PVD), sputtering, atomic layer deposition (ALD) or other like deposition processes. A planarization or an etch back process may follow the deposition of power rail 210 such that a top surface of power rail 210 is coplanar with a top surface of ILD material 220.

In general, power rail 210 makes contact with a top surface of source/drain contact 110. In embodiments of the present invention, the length of power rail 210 is oriented in a direction that is orthogonal (i.e., perpendicular) to the direction of the length of source/drain contact 110. As described with reference to source/drain contact 110, source/drain contact 110 may be a source/drain contact line in a first direction, wherein a length of the line is greater than a width of the line and power rail 210 may be oriented in a second direction, rotated ninety degrees compared to the first direction. Power rail 210 similarly is of a length greater than its width.

FIG. 3A depicts a top view of fabrication steps and FIG. 3B depicts a cross-sectional view along section line A of FIG. 3A. FIGS. 3A-3B depict the formation and patterning of hardmask 310 and the formation of a notch in power rail 210 and a cut through source/drain contact 110, in accordance with an embodiment of the present invention.

Hardmask 310 may be formed by any suitable deposition process such as, for example, chemical vapor deposition (CVD) or plasma enhanced chemical vapor deposition (PECVD). Hardmask 310 may include a hardmask material such as, for example, silicon dioxide and/or silicon nitride.

Hardmask 310 may be patterned using photoresist to expose areas where the cut (see cut 410, as more specifically labeled in FIGS. 4A and 4B) is desired through at least a portion of power rail 210, creating a notch, and through an entire section of source/drain contact 110, creating a cut. Hardmask 310 may be utilized during an etching process in the creation of the cut 410. The etching process only removes portions of the device not protected by hardmask 310 and the etching process stops at the FEOL device(s) after cutting through source/drain contact 110.

Subsequent to the creation of cut 410, source/drain contact 110 is split into two separate portions. In some embodiments, the cut 410 creates a notch within power rail 210 and a first portion of the source/drain contact 110 is in contact with the power rail 210 with a sidewall surface coplanar with an inner edge of the notch. In some embodiments, a shortest distance between the first portion of source/drain contact 110 and the second portion of the source/drain contact 110 is less than the width of power rail 210. In some embodiments, a surface of the second source drain contact is centered relative to the notch that is present within the power rail.

FIG. 4A depicts a top view of fabrication steps and FIG. 4B depicts a cross-sectional view along section line A of FIG. 4A. FIGS. 4A-4B depict the removal of hardmask 310, in accordance with an embodiment of the present invention.

In some embodiments, subsequent to the formation of cut 410, hardmask 310 is removed. In general, the process of removing hardmask 310 involves the use of an etching process such as RIE, laser ablation, or any etch process which can be used to selectively remove a portion of material, such as hardmask 310. In some embodiments, prior to the removal of hardmask 310, the photoresist (not shown) is removed. The process of removing the photoresist is similar to that of the process of removing hardmask 310.

The resulting structure includes a transistor source/drain contact (source/drain contact 110) in a first orientation and a power rail (power rail 210) in perpendicular orientation to the first orientation of the transistor source/drain contact (source/drain contact 110). A notch (cut 410) cuts through a portion of the power rail (power rail 210) and through the transistor source/drain contact (source/drain contact 110). The notch (cut 410) has a width (width 420) that is less than a width of the power rail (power rail 210).

Subsequent to the formation of cut 410 and the removal of hardmask 310, any additional BEOL interconnect features that are desired may be formed to finalize the semiconductor structure.

The final structure depicted in FIG. 4 does not include any FEOL and additional BEOL features that may be desired in various semiconductor structures that utilize embodiments of the present invention.

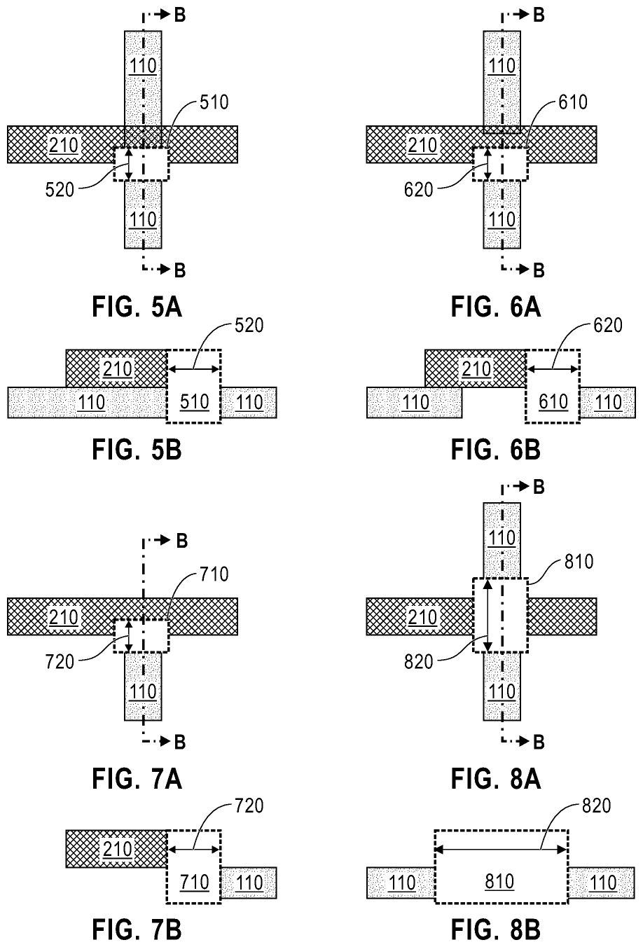

FIGS. 5A-5B through FIGS. 8A-8B depict a variety of example embodiments of the present invention and illustrate a variety of variations in final structure as compared to the embodiment described with respect to FIGS. 4A-4B. Each of FIGS. 5A-FB through FIGS. 8A-8B has been simplified to only depict the source/drain contact 110, power rail 210, and cuts (e.g., cuts 510, 610, 710, 810).

FIG. 5A depicts a top view of and FIG. 5B depicts a cross-sectional view along section line A of FIG. 5A. FIG. 5A depicts the embodiment depicted in FIGS. 4A-4B with the removal of ILD material 220. Cut 510 and width 520 are each comparable to the cut 410 and width 420 depicted in FIGS. 4A and 4B.

FIG. 6A depicts a top view and FIG. 6B depicts a cross-sectional view along section line A of FIG. 6A. FIGS. 6A and 6B depict an embodiment in which a portion of source/drain contact 110 has been removed beneath power rail 210 such that power rail 210 overhangs over a portion of source/drain contact 110. In some embodiments, the removal of this portion of source/drain contact 110 may have been performed by an etching process, such as RIE, wet etch, or any etch process which can be used to selectively etch. The example depicted in FIGS. 6A and 6B includes a cut 610 and width 620 that are each comparable to the cut 410 and width 420 depicted in FIGS. 4A and 4B.

FIG. 7A depicts a top view and FIG. 7B depicts a cross-sectional view along section line A of FIG. 7A. FIGS. 7A and 7B depict an embodiment in which source/drain contact 110 is only present on one side of power rail 210. The example depicted in FIGS. 7A and 7B include a cut 710 and width 720 that are each comparable to the cut 410 and width 420 depicted in FIGS. 4A and 4B.

FIG. 8A depicts a top view and FIG. 8B depicts a cross-sectional view along section line A of FIG. 8A. FIGS. 8A and 8B depict an embodiment in which cut 810 cuts entirely through the intersection of source/drain contact 110 and power rail 210. In the example depicted in FIGS. 8A and 8B, cut 810 is more significant in that, instead of merely creating a notch in power rail 210, power rail 210 is cut into two separate sections. In such an embodiment, the width 820 of cut 810 is larger than a width of power rail 210.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application is not limited to the exact forms and details described and illustrated, but fall within the scope of the appended claims.

What is claimed is:

1. A structure comprising:
a transistor source/drain contact in a first orientation;
a power rail on the transistor source/drain contact in a second orientation, wherein the second orientation is perpendicular to the first orientation; and
a cut passing through the power rail and the transistor source/drain contact at a location of intersection of the power rail and the transistor source/drain contact.

2. The structure of claim 1, wherein the cut passes through only a portion of a width of the power rail such that the power rail is notched.

3. The structure of claim 1, wherein the cut passes through an entire width of a portion of the transistor source/drain contact.

4. The structure of claim 1, wherein a length of the cut along the first orientation is less than a width of the power rail.

5. The structure of claim 2, wherein a distance across the cut from an inside edge of the notch on the power rail to the transistor source/drain contact is less than the width of the power rail.

6. The structure of claim 5, wherein the inside edge of the notch on the power rail is aligned with an end of the transistor source/drain contact.

7. The structure of claim 1, wherein a width of the power rail is greater than a width of the transistor source/drain contact.

8. The structure of claim 1, wherein a surface of the transistor source/drain contact is coplanar with a surface of the power rail.

9. The structure of claim 1, wherein the transistor source/drain contact comprises a first transistor source/drain contact connected to the power rail and a second transistor source/drain contact.

10. The structure of claim 9, wherein a distance between the first transistor source/drain contact and the second transistor source/drain contact is less than a width of the transistor source/drain contact.

11. The structure of claim 9, wherein a surface of the power rail closest to the second transistor source/drain contact is closer to the second transistor source/drain contact than a surface of the first transistor source/drain contact closest to the second transistor source/drain contact.

12. The structure of claim 1, wherein the cut passes through an entire width of a portion of the transistor source/drain contact and an entire width of a portion of the power rail.

13. The structure of claim 1, further comprising an interlayer dielectric material layer on a top surface of the transistor source/drain contact and a sidewall of the power rail.

14. A structure comprising:
a first source/drain contact with a length greater than a width, the length of the first source/drain contact in a first direction;
a second source/drain contact with a length greater than a width, the length of the second source/drain contact in the first direction; and
a power rail with a length greater than a width, the length of the power rail in a second direction, wherein:
the second direction is perpendicular to the first direction;
the power rail contacts the first source/drain contact; and
a notch is present within the power rail.

15. The structure of claim 14, wherein the width of the power rail is greater than the width of the first source/drain contact and the width of the second source/drain contact.

16. The structure of claim 14, a shortest distance between an end of the first source/drain contact and an end of the second source/drain contact is less than the width of the power rail.

17. The structure of claim 14, wherein an inside surface of the notch is coplanar with a surface of the first source/drain contact.

18. The structure of claim 14, further comprising an interlayer dielectric material layer on: a top surface of the first source/drain contact, a top surface of the second source/drain contact, and a sidewall of the power rail.

19. The structure of claim 14, wherein a surface of the second source drain contact is centered along the second direction relative to the notch that is present within the power rail.

20. A method of forming a structure comprising:
forming a transistor source/drain contact in a first orientation;
forming a power rail on the transistor source/drain contact in a second orientation, wherein the second orientation is perpendicular to the first orientation;
forming a hardmask;
patterning the hardmask to expose a location of an intersection of the power rail and the transistor source/drain contact; and
etching the location unprotected by the hardmask to create a cut passing through the power rail and the transistor source/drain contact.
